(19) United States
(12) Patent Application Publication
(10) Pub. No.: US 2011/0287607 A1
(43) Pub. Date: Nov. 24, 2011

(54) METHOD AND APPARATUS FOR IMPROVED WAFER SINGULATION

(75) Inventors: Yasu Osako, Lake Oswego, OR (US); Bong Cho, Beaverton, OR (US); Daragh Finn, Beaverton, OR (US); Andrew Hooper, Portland, OR (US); James O'Brien, Bend, OR (US)

(73) Assignee: ELECTRO SCIENTIFIC INDUSTRIES, INC., Portland, OR (US)

(21) Appl. No.: 13/076,238

(22) Filed: Mar. 30, 2011

Related U.S. Application Data
(60) Provisional application No. 61/320,476, filed on Apr. 2, 2010.

(51) Int. Cl. H01L 21/78; B23K 26/00

(52) U.S. Cl. 438/462; 219/121.72; 257/E21.599

(57) ABSTRACT

Laser singulation of electronic devices from semiconductor substrates including wafers is performed using up to 3 lasers from 2 wavelength ranges. Using up to 3 lasers from 2 wavelength ranges permits laser singulation of wafers held by die attach film while avoiding problems caused by single-wavelength dicing. In particular, using up to 3 lasers from 2 wavelength ranges permits efficient dicing of semiconductor wafers while avoiding debris and thermal problems associated with laser processing die attach tape.

### TECHNICAL FIELD

The present invention regards aspects of laser singulation of electronic substrates. In particular it regards laser singulation of electronic devices from semiconductor substrates including wafers using up to 3 lasers from two wavelength ranges. In more particular it regards efficient singulation of electronic devices from substrates including wafers held with die attach film while avoiding problems associated with laser processing die attach film.

### BACKGROUND OF THE INVENTION

Electronic devices are nearly universally manufactured by constructing multiple copies of the circuit or device on a large substrate in parallel. In particular, devices which rely on semiconducting materials are constructed on wafers made of silicon, germanium, sapphire, gallium arsenide, indium phosphide, diamond or ceramic. These wafers typically need to be singulated into individual devices. Singulation can be performed by first scribing the wafer with a diamond saw or laser followed by cleaving or by dicing. Scribing is defined as creating a modified region on the surface or within the volume of a wafer with a laser or diamond saw which facilitates cracking and thereby the separation of the wafer proximate to the scribe. Dicing is defined as performing through cuts or near through-cuts in the wafer with a laser or diamond saw so that the wafer can be subsequently separated into individual devices with minimal force. FIG. 1 shows a typical wafer 10 containing multiple devices 12 separated by orthogonal streets 14, 16. Streets are regions of the wafer which are deliberately devoid of active circuitry to permit scribing or dicing in the street region without damaging active circuitry. The wafer 10 is supported by tape 20 attached to a tape frame 18. Laying out streets in this fashion permits the wafer 10 to be singulated by scribing or dicing linearly along the streets 14, 16 thereby separating the individual devices 12. Using a laser rather than a diamond-coated saw blade also permits scribing or dicing in patterns other than linear. Wafers 10 are often adhesively attached to a die attach film (DAF)(not shown) which is then attached to the tape 20 which is in turn attached to the tape frame 18 during manufacturing to permit handling the wafer 10.

The advantages of using lasers to singulate devices constructed on a wafer is known, as shown in U.S. Pat. No. 6,960,813, METHOD AND APPARATUS FOR CUTTING DEVICES FROM SUBSTRATES, inventor Kuo-Ching Liu, issued Nov. 1, 2005. In this patent, a UV pulsed laser is used in cooperation with a porous vacuum chuck to singulate semiconductor wafers. No mention is made of issues which may arise because of the use of DAF. DAF is an engineered adhesive material designed to remain attached to the device following singulation to permit the device to be adhesively attached to other substrates or devices as part of the further packaging process. As such the DAF must maintain its bond to the wafer it is bonded to and remain undamaged and free of debris following laser dicing in order to function properly. Exemplary DAF is manufactured by Al Technology, Inc. Princeton Junction, N.J. 08550. Typically during the dicing process the wafer, the DAF and possibly part of the tape are cut by the laser or the saw. Laser dicing of wafers has many advantages over diamond saw dicing; however, removing the DAF in the desired region associated with the through cut with the same laser that makes the through cut has the disadvantages of low efficiency and increased debris and damage. FIG. 2 shows a cross-sectional diagram of a wafer 30 with applied layers containing active devices 32, 34 and a street 36. The wafer 30 is attached to DAF 38 supported by tape 40 which is attached to a tape frame 42.

The presence of DAF on a wafer can cause problems with laser singulation. Attempting to remove DAF using the same UV laser that is used to through cut the wafer can cause excessive debris and thermal damage to the wafer and DAF. FIG. 3 is a microphotograph of a portion of the bottom side of a silicon wafer 30 after being diced by a 355 nm UV laser (not shown) having 2.8 W of power at 30 KHz pulse repetition rate a 40 micron wide shaped beam using nanosecond pulse widths showing the exposed DAF 32, 34 and the kerf 36 formed by the through cut. The kerf is bordered on both sides by debris and damaged DAF 38 as a result of the laser through cut. In this microphotograph, the through cut is about 50 microns wide. Thermal damage, including delamination of DAF from the wafer and debris including melted or vaporized DAF material redeposited on the sidewalls of the kerf. These types of debris or damage caused by prior art approaches to laser singulation in the presence of DAF can cause problems in subsequent manufacturing steps. For example, delamination or excessive debris could hinder proper placement when DAF is used to pick and position the device for packaging. In addition excessive debris redeposited on the sidewalls of the kerf could hinder further processing such as sidewall etching.

In U.S. Pat. No. 6,562,698, DUAL LASER CUTTING OF WAFERS, inventor Ran Manor, issued May 13, 2003, discusses singulating wafers with two laser beams at two different wave lengths with the aim of removing a layer of material from the wafer to permit the second wavelength to more efficiently process the wafer. No mention is made of DAF or tape or issues associated with laser singulating wafer in the presence of DAF. U.S. patent application no. 2008/0160724, METHOD OF DICING, inventors Hyun-Jung Song, Kak-Kyoon Byun, Jong-Bo Shim and Min-Ok Na, published Jul. 3, 2008, discussed issues associated with laser dicing in the presence of DAF and propose modifying DAF adhesive formulas and adding steps and material to the process by which DAF is applied to the wafer during manufacturing. Both of these approaches have drawbacks that make them less than desirable solutions. U.S. Pat. No. 6,992,026, LASER PROCESSING METHOD AND LASER PROCESSING APPARATUS, inventors Fumitsugo Fukuyo, Kenshi Fukumitsu, Naoki Uchiyama, Toshimitsu Wakuda, issued Jan. 31, 2006 proposes the singulation of the wafer by focusing the laser inside the bulk wafer material to create cracks along the scribing streets to guide subsequent cleaving. The devices are separated by stretching the tape and therefore the wafer before through cutting the DAF with a laser through the so formed openings between devices. The disadvantage of this approach is the difficulty in performing positional alignment of the laser beam with respect to the opening for the cut due to the nonlinear and irregular expansion of devices on DAF and tape. Re-aligning the wafer following separation of the devices on DAF also takes time, thereby slowing throughput undesirably.

What these approaches have in common is a desire to singulate wafers in the presence of DAF efficiently without undesirable damage or debris. What is required then and has not been disclosed by the prior art is a method for efficiently laser singulating electronic devices from electronic substrates such as wafers while avoiding problems associated with laser processing die attach film.

### SUMMARY OF THE INVENTION

Aspects of this invention represent an improved method for singulation of wafers mounted on die attach film (DAF) with a laser processing system. The wafer has predefined streets and a layer of material on the surface opposite the DAF. The laser processing system has first, second, and third lasers having first, second and third laser parameters including wavelengths in the visible or ultraviolet (UV), infrared (IR), and visible or ultraviolet (UV) respectively. A maximum surface texture of the wafer is determined that permits backside removal of the DAF with the second laser using predetermined second laser parameters. First laser parameters are determined that permit the first laser to remove portions of the layer of material from the wafer in a desired region so that substantially all of the layer of material is removed from the desired region and the surface texture of the resulting surface within the desired region is less than said determined maximum surface texture. The first laser is then directed to remove the layer of material from the wafer within a desired area substantially within the streets using the said laser parameters. Following this the second laser is directed to perform backside removal of portions of the die attach film using the predetermined second laser parameters in regions aligned with the streets. Then the third laser is directed to perform through cuts in the wafer with the predetermined third laser parameters substantially within the streets thereby singulating the wafer.

Aspects of this invention also singulate devices on wafers by forming a deteriorated region in the DAF by backside illumination. A layer or layers of materials are removed from the surface of the wafer with a visible or UV laser leaving the surface roughness less than 10% of the wavelength of the IR laser to be used to form a deteriorated region in the DAF. Following through cutting of the wafer with a visible or UV wavelength laser the tape is stretched to separate the devices and since the DAF has a deteriorated region aligned with the streets where most of the tension will be applied to the DAF by the stretching tape, the DAF separates where desired. Forming deteriorated regions can require less energy and create less debris following separation than removal of DAF in desired regions.

Backside DAF removal refers to removing or deteriorating DAF by directing laser pulses to the DAF through the wafer by selecting laser wavelengths that are preferentially absorbed by the DAF and are substantially transparent to the wafer. Lasers with wavelengths in the IR regions are substantially transparent to many wafer materials including silicon and germanium but are readily absorbed by DAF, thereby permitting the laser processing system to focus the laser pulses onto the DAF through the wafer. Aspects of the current invention remove material in a layer or layers on the front or top surface of the wafer with a visible or UV laser to expose the surface of the wafer in order to permit backside removal of DAF by directing IR laser radiation through the wafer. In order to efficiently transmit laser power through the surface of the wafer to the DAF, the newly exposed surface of the wafer must be smooth enough to transmit laser energy without excessive scatter or diffusion. The surface roughness of the exposed wafer surface as measured by RMS average height distribution measured in microns along an approximately 75 micron long line should be less than 10% of the length of the wavelength of laser radiation to be used. In this case, using a 10.6 micron CO2 laser would require that the RMS surface roughness measure less than 1.06 microns. Backside removal of DAF with a CO2 gas laser operating at 10.6 microns through a silicon wafer with surface roughness of less than 10% of the laser wavelength following removal of a surface layer according to aspects of this invention quickly and cleanly removes DAF from the desired region while avoiding excessive debris or thermal damage to the wafer.

An ESI model 9900 Ultra-thin Wafer Dicing System is an exemplary laser processing system that can be adapted to implement aspects of this invention. This laser processing system is manufactured by Electro Scientific Industries, Inc., Portland Oreg. 97239. This system may be adapted by using three lasers and three sets of laser optics to dice wafers; a visible or UV wavelength laser and optics to remove surface layers, an IR laser and optics to perform backside removal or deterioration of DAF and a visible or UV wavelength laser and optics to through cut the wafer. Alternatively the laser processing system may be adapted by using two laser and two sets of laser optics; a visible or UV laser and optics to remove surface layers and through cut the wafer and an IR laser and optics to perform backside removal or deterioration of DAF. The laser processing system may also be adapted by using single laser which can switch or be switched between IR and visible or UV wavelengths, optics to handle both wavelengths and has sufficient power to be able to process wafers efficiently.

Singulation of electronic devices from a wafer in this manner is efficient since the wafer does not have to be moved or re-aligned during the process as is required by other approaches to solving the problems associated with singulation of wafers on DAF. Aspects of this invention also provide a substantially debris-free and undamaged wafer following singulation due to the limited amount of debris and thermal damage caused by removal of the DAF by laser. In addition the DAF which remains attached to the electronic device by design is substantially debris-free and is trimmed accurately to the device.

### BRIEF DESCRIPTION OF THE DRAWINGS

FIG. 1. Prior art wafer

FIG. 2. Prior art Cross-section of wafer on DAF and tape

FIG. 3. Prior art through cut wafer with DAF

FIG. 4. % Absorption vs. wavelength for silicon

FIGS. 5a-f. Laser dicing with DAF

FIG. 6a-g. Surface roughness measure of wafer following removal of layer

FIG. 7. DAF after singulation by CO² laser

FIG. 8. Silicon wafer with attached DAF following singulation

FIG. 9. Laser dicing with DAF

FIG. 10 Laser processing system using three lasers

FIG. 11 Laser processing system using two lasers

FIG. 12 Laser processing system using one laser

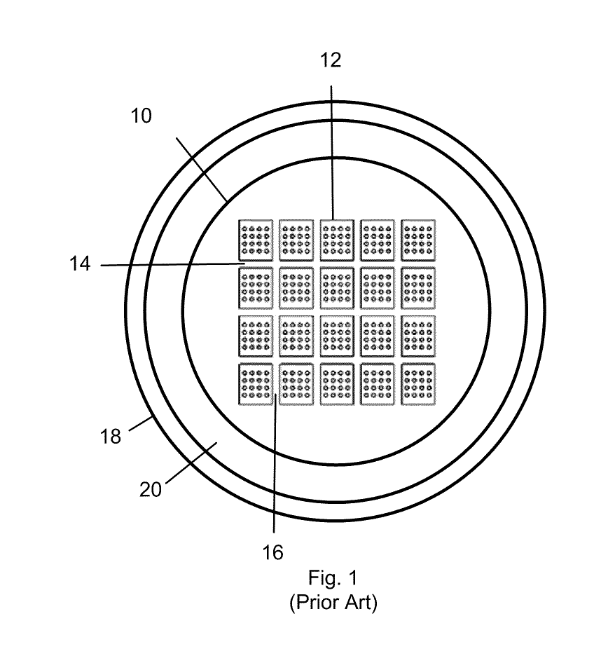

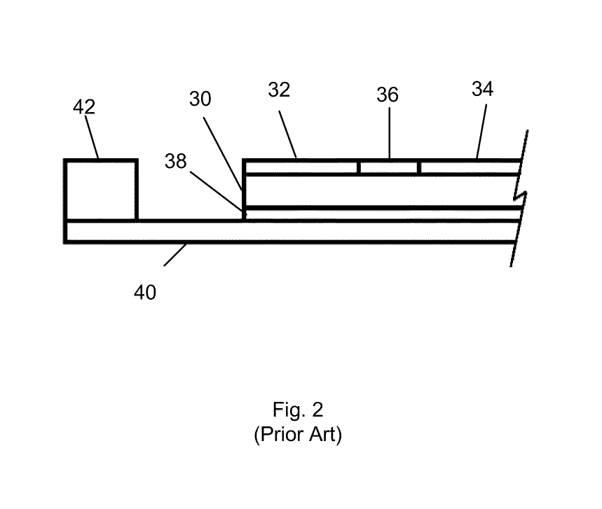

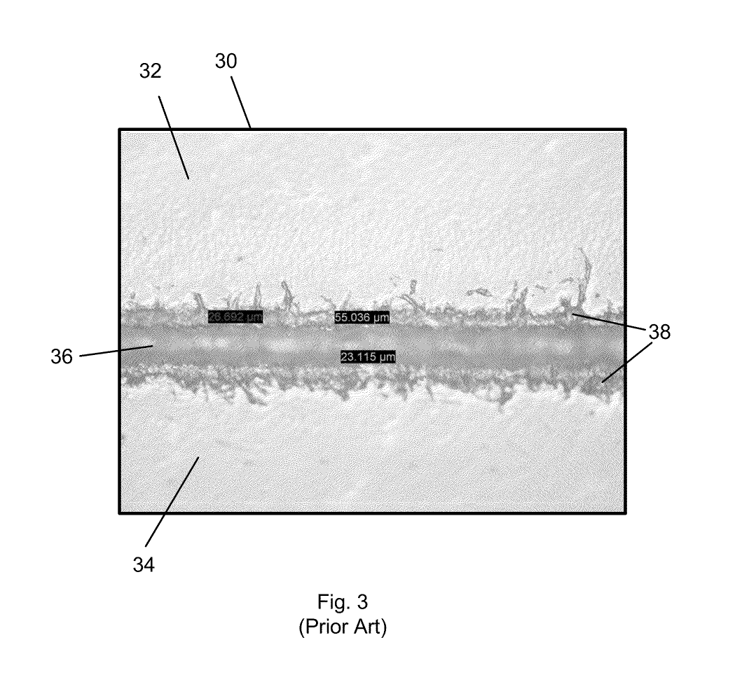

### DETAILED DESCRIPTION OF PREFERRED EMBODIMENTS

Embodiments of this invention represent an improved method for singulation of wafers mounted on die attach film (DAF) with a laser processing system. The wafer has predefined streets and a layer of material on the surface opposite the DAF. The laser processing system has first, second, and third lasers having first, second and third laser parameters. A maximum surface texture of the wafer is determined that permits backside removal of the DAF with the second laser using predetermined second laser parameters. First laser parameters are determined that permit the first laser to remove portions of the layer of material from the wafer in a desired region so that substantially all of the layer of material is removed from the desired region and the surface texture of the resulting surface within the desired region is less than said determined maximum surface texture. The first laser is then directed to remove the layer of material from the wafer within a desired area substantially within the streets using the said laser parameters. Following this the second laser is directed to perform backside removal of portions of the die attach film using the predetermined second laser parameters in regions aligned with the streets. Then the third laser is directed to perform through cuts in the wafer with the predetermined third laser parameters substantially within the streets thereby singulating the wafer.

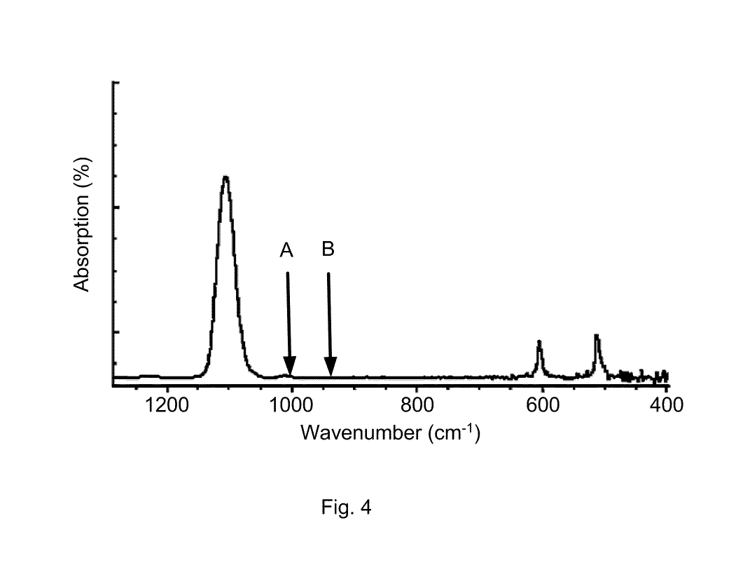

Backside DAF removal refers to removing DAF by directing laser pulses to the DAF through the wafer by selecting laser wavelengths that are preferentially absorbed by the DAF and are substantially transparent to the wafer. Lasers with wavelengths in the IR regions are substantially transparent to many wafer materials including silicon and germanium but are readily absorbed by DAF, thereby permitting the laser processing system to focus the laser pulses onto the DAF through the wafer. FIG. 4 is a graph plotting percent absorption vs. wavenumber measured in inverse centimeters for silicon. The arrows A and B represent the principle wavelengths emitted by a CO2 laser (10.6 and 9.4 microns) and show that silicon has very low absorption and hence very high transmission of laser wavelengths in this range.

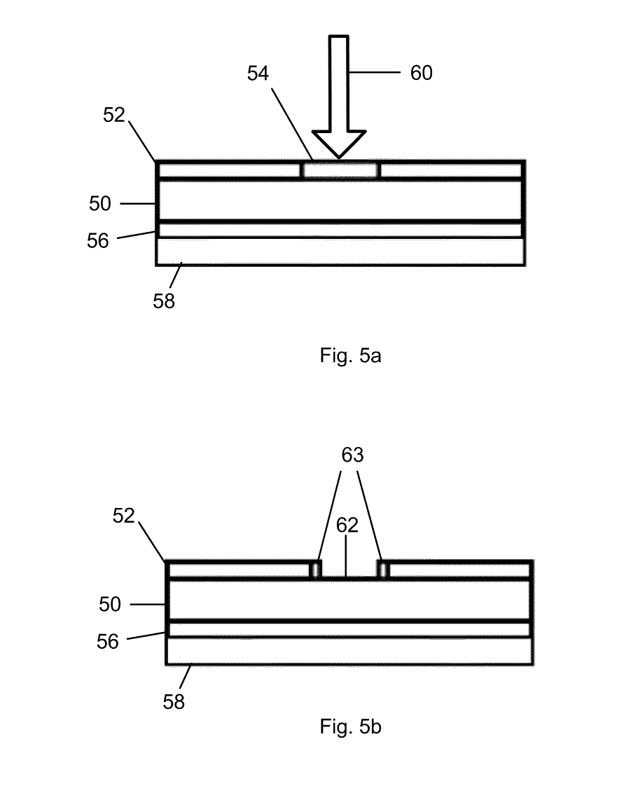

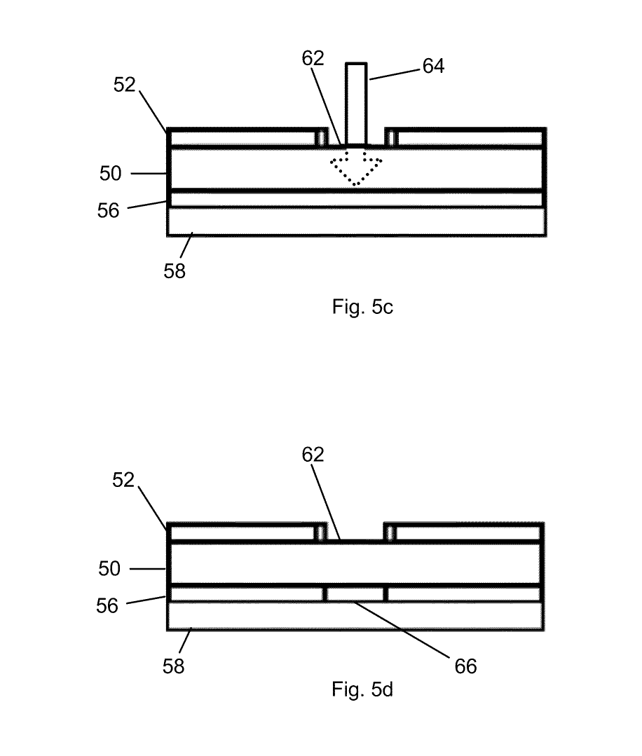

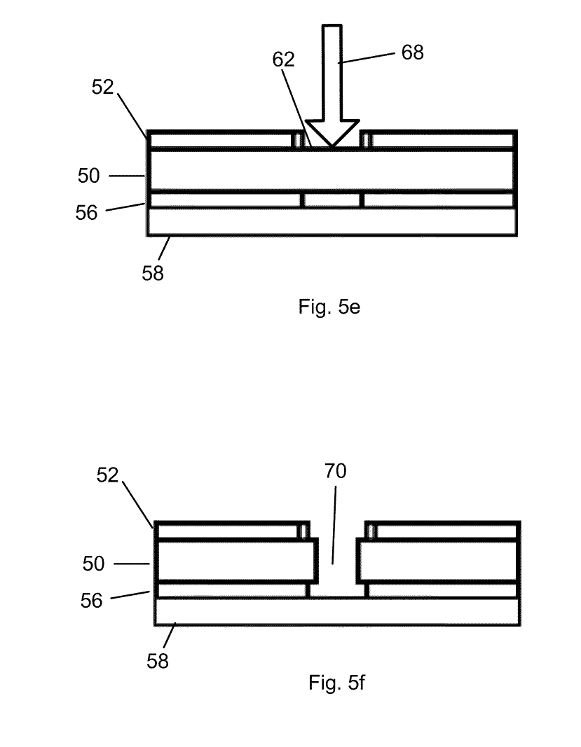

Embodiments of the current invention remove material in a layer or layers on the front or top surface of the wafer with a visible or UV laser to expose the surface of the wafer itself in order to permit backside removal of DAF by directing IR laser radiation through the wafer. FIGS. 5a through 5f illustrate this process by showing a cross-sectional view of a wafer 50 on DAF 56 supported by tape 58. In FIG. 5a a wafer 50 on DAF 56 supported by tape 58 has a surface layer 52 containing active circuitry with a street 54 indicated. First laser pulses 60 are directed to the street area 54 to remove material 52 and expose the surface of the wafer 50. FIG. 5b shows the wafer 50 after partial removal of the surface layer 52, which exposes the surface of the wafer 62. Also shown are regions of the street 63 which remain following material removal. FIG. 5c shows second laser pulses 64 being focused through the exposed surface of the wafer 62 onto the surface of the DAF 56. As shown in FIG. 5d, the second laser pulses 64 have removed or caused deterioration in a region of the DAF 66 aligned with the exposed region of wafer 62. In FIG. 5e, third laser pulses 68 are directed to the exposed surface of the wafer 62. In FIG. 5f the third laser pulses 68 have formed a through cut 70 in the wafer 50 in alignment with the removed or deteriorated DAF 66 to thereby singulating the wafer 50.

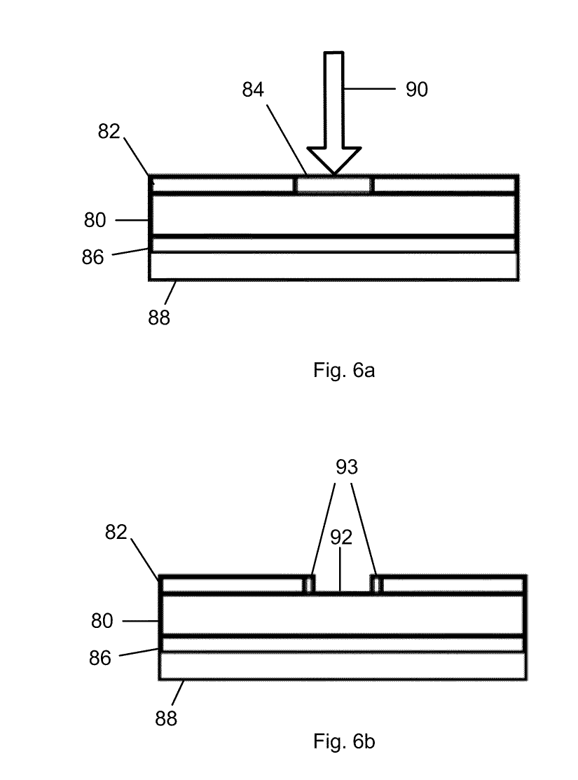

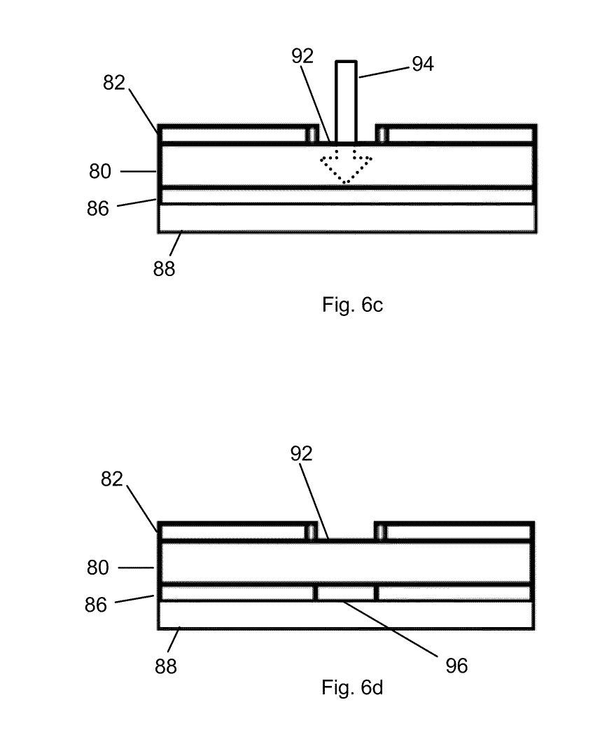

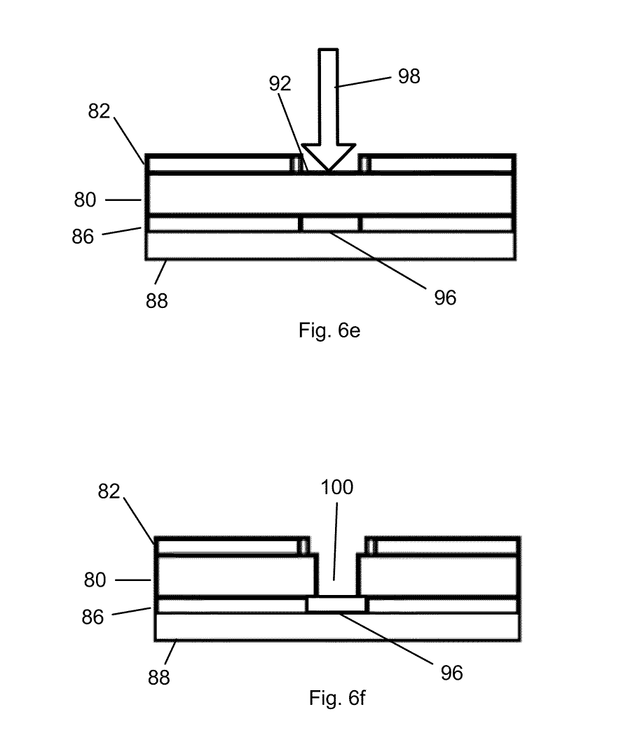

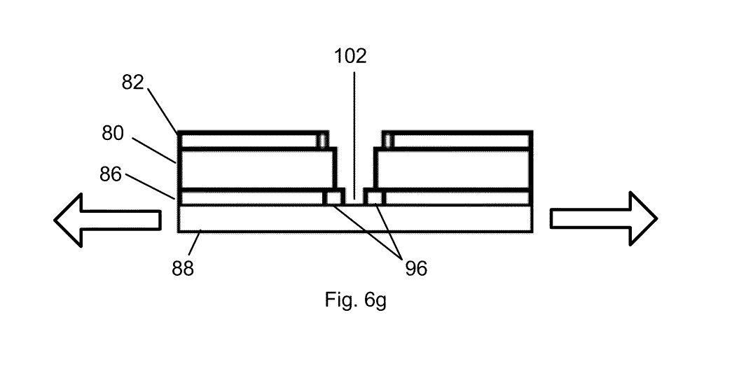

Embodiments of this invention also singulate devices on wafers by forming a deteriorated region in the DAF by backside illumination. FIGS. 6a through 6f illustrate this process. In FIG. 6a, a wafer 80 with a topside layer 82 having a street 84 on DAF 86 and tape 88 is illuminated by a visible or UV laser 90. FIG. 6b shows the topside layer 82 with the surface of the wafer exposed 92. Note that portions of the street 93 may remain adjacent to the exposed wafer 92. This layer or layers of material is removed from the surface of the wafer with a visible or UV laser leaving the surface roughness less than 10% of the wavelength of the IR laser to be used to form a deteriorated region in the DAF. FIG. 6c shows the IR laser pulses 94 being directed to the DAF 86 through the exposed surface of the wafer 92. FIG. 6d shows the deteriorated region 96 created in the DAF 86. FIG. 6e shows visible or UV laser pulses 98 being directed to the wafer 80 to form a through cut. FIG. 6f shows the through cut 100 in wafer 80 which stops at the deteriorated region 96 of DAF 86. FIG. 6g shows the tape 88 stretched in the directions of the arrows to separate the wafer 80. Since the DAF 86 has a deteriorated region 96 aligned with the though cut 100 tension will be applied to the deteriorated region 96 by the stretching tape 88, thereby forming a separation 102 in the deteriorated region 96, causing the DAF to separate where desired. Forming deteriorated regions can require less energy and create less debris following separation than complete removal of DAF.

Embodiments of this invention focus laser pulses at or within the DAF on the bottom side of the wafer to remove or alter the DAF while the wafer is fixtured and aligned on the laser processing system. Backside removal of DAF depends upon starting the removal process at an edge of the wafer and proceeding towards the interior in order to provide a path for the vaporized DAF material to escape without cooling and redepositing material. High pressure gas created by the laser pulses ejects the vaporized or melted DAF material away from the laser machining site and thereby keeps the debris from forming. Embodiments of this invention also singulate devices on wafers by forming a deteriorated region in the DAF by backside laser processing. In this case the laser energy used is not sufficient to ablate or vaporize the DAF but rather causes a deteriorated region in the DAF which permits the DAF to separate cleanly and easily in desired locations when subjected to tension caused by stretching the tape to separate the devices.

Embodiments of this invention remove a layer or layers of material from the surface of a wafer to permit a second laser to remove or deteriorate DAF through the wafer. In order to efficiently transmit laser power through the surface of the wafer to the DAF, the newly exposed surface of the wafer must be smooth enough to transmit laser energy without excessive scatter or diffusion. The surface roughness of the exposed wafer surface as measured by the maximum height difference in microns of points measured along an approximately 75 micron-long line should be less than 10% of the length of the wavelength of laser radiation to be used. For example, using a 10.6 micron CO2 laser would require that the surface roughness measure less than 1.06 microns. Backside removal of DAF with a CO2 gas laser operating at 10.6 microns through a silicon wafer with surface roughness of less than 10% of the laser wavelength following removal of a surface layer according to embodiments of this invention quickly and cleanly removes DAF from the desired region while avoiding excessive debris or thermal damage to the wafer.

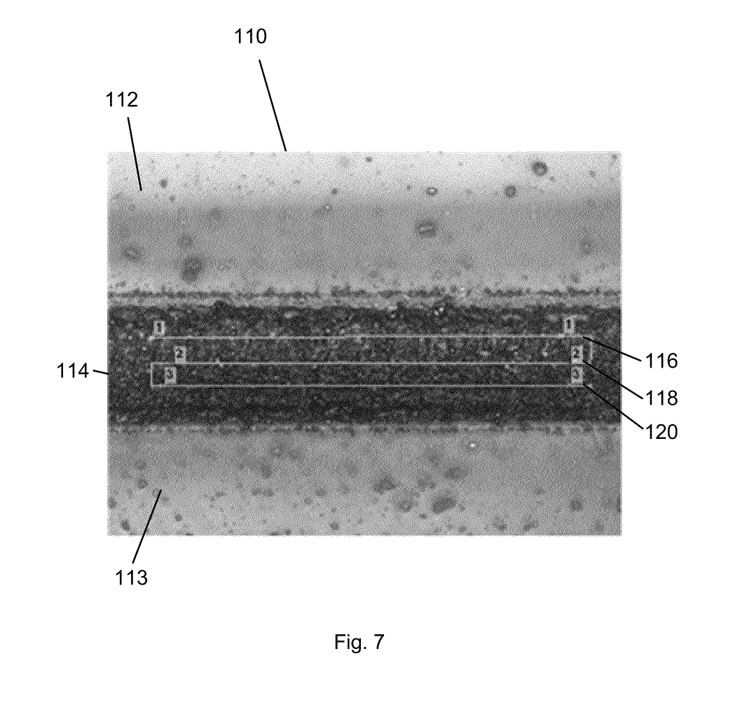

FIG. 7 shows a microphotograph of a wafer 110 having a surface layer of material 112, 113 which has been removed to expose the surface of the wafer 114. The material was removed using a 16 W UV laser (not shown) emitting pulses with pulse duration between 10 and 1000 picoseconds and pulse energy of less than 200 uJ at 355 nm using a 45 micron spot square-shaped (top hat) beam focused at the surface layer 112, 113. Shown in this microphotograph are three line segments 116, 118, 120 along which samples of the height of the surface were measured and averaged. As can be seen, the maximum height difference for all samples averaged is 0.568 which is less than the desired maximum value of 1.06. The data from these measurements is shown in Table 1.

TABLE 1

| Profile | Horizontal | Height | Height |
|---|---|---|---|
| # | distance | Difference | Average |
| All | 251.712 μm | 0.568 μm | 3.093 μm |
| Seg. 1 | 75.275 μm | 0.317 μm | 3.755 μm |
| Seg. 2 | 72.891 μm | 0.521 μm | 2.511 μm |
| Seg. 3 | 74.594 μm | 0.780 μm | 3.051 μm |

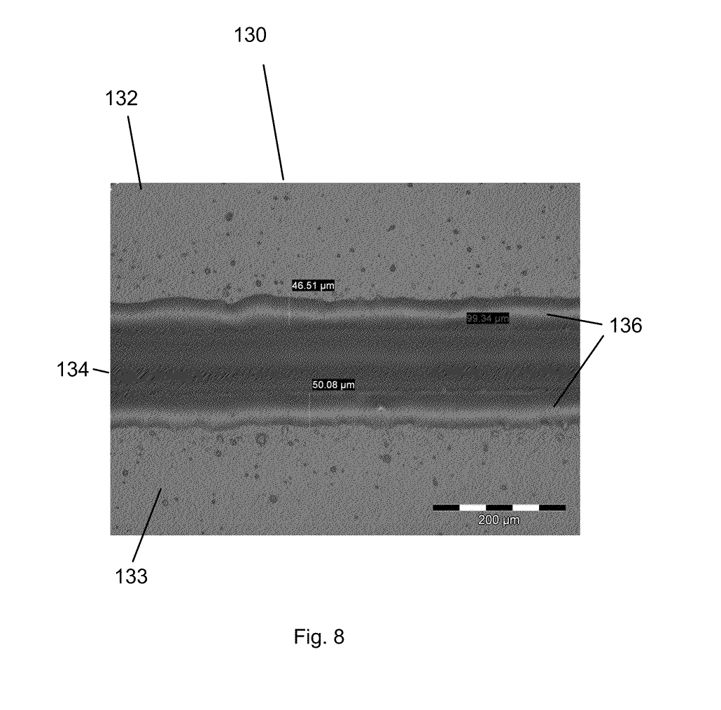

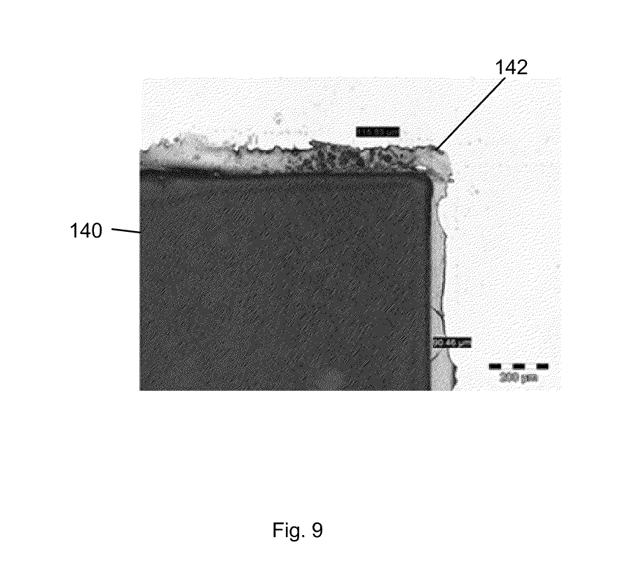

FIG. 8 is a microphotograph showing tape 130 with overlaying DAF 132, 133 following processing according to embodiments of this invention. The wafer (not shown) has been removed to show the debris-free and smooth edges 136 of the kerf 134 formed in the DAF 132, 133, a desired result. The kerf 134 was formed in the DAF 132, 133 using a 200 W CO2 laser (not shown) operating at 10.6 microns using a clipped Gaussian beam focused at the DAF through the wafer (not shown). Clipping a Gaussian beam refers to passing the laser pulse through an aperture which can be circular or otherwise shaped to pass only the central part of the laser pulse and block transmission of the outermost laser energy. FIG. 9 shows a microphotograph of a portion of a silicon wafer 140 which has been singulated along with the underlying DAF 142 to form a singulated electronic device according to an embodiment of this invention. The surface layer (not shown) was removed with a 16 W UV laser (not shown) operating at 355 nm with a square shaped beam focused to a 10 micron focal spot at the surface layer. The DAF 142 was then processed with a 200 W CO2 IR laser (not shown) operating at 9.4 micros with a square shaped beam focused to a 50 micron spot at the DAF 142. Following this the wafer 140 was through cut with a 16 W UV laser (not shown) operating at 355 nm with a square shaped beam focused to a 10 micron focal spot at the wafer 140. Note that the DAF 142 is continuously attached to the silicon wafer 140 and is well within acceptable size and debris limits, a desired result.

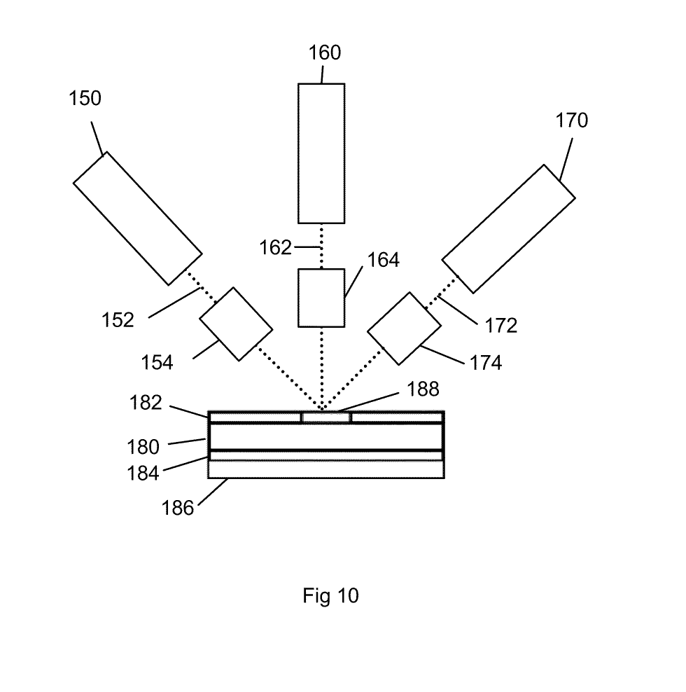

An ESI model 9900 Ultra-thin Wafer Dicing System is an exemplary laser processing system that can be adapted to implement aspects of this invention. This laser processing system is manufactured by Electro Scientific Industries, Inc., Portland Oreg. 97239. This system is described in publication “Model 9900 Site Requirements and Installation Guide”, ESI part no. 187054a and is included herein in its entirety by reference. In an embodiment of this invention this system is adapted by using three lasers and three sets of laser optics to dice wafers as shown in FIG. 10. Firstly, a visible or UV wavelength laser 150 produces visible or UV laser pulses 152 which are directed by visible or UV laser optics 154 to remove surface layer 182 within street 188 on wafer 180 held on DAF 184 attached to tape 186. Secondly, an IR laser 160 produces IR laser pulses 162 which are directed by IR laser optics 164 to perform backside removal or deterioration of DAF 184 through wafer 180 following removal of surface layer 182 in street 188. Thirdly, a visible or UV wavelength laser 170 produces visible or UV laser pulses 172 which are directed by visible or UV optics 174 to through cut wafer 180.

A laser which may be used as the first 150 and third 170 visible or UV laser is the Coherent Avia, manufactured by Coherent Inc., Santa Clara, Calif. 95054. This laser is a Q-switched Nd:YVO4 conventional solid state diode-pumped laser which operates at 355 nm wavelength at a pulse repetition rates of up to 100 kHz and average power of 16 W. The visible or UV laser optics 154, 174 can include temporal pulse shaping optics such as an AOM or EOM, spatial pulse shaping optics such as diffractive beam shaping optics or collimators, beam steering optics such as AOMs or galvanometers and field optics to direct the shaped, steered laser pulses to the workpiece. The IR laser 160 may be a Coherent Diamond K-Series CO2 laser manufactured by Coherent Inc., Santa Clara, Calif. 95054 which operates at 9.6 micron wavelength at pulse repetition rates of up to 100 KHz and average power of over 200 W. The IR optics 164 contain the same elements as the visible or UV laser optics 154, 174 and perform the same basic functions except that the IR optics 164 are optimized to process IR wavelengths.

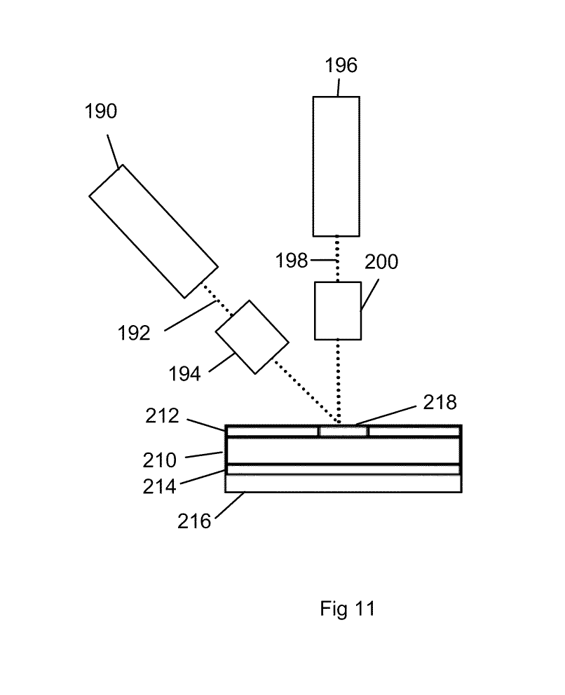

Alternatively, embodiments of this system adapt the laser processing system by using two laser and two sets of laser optics as shown in FIG. 11. Firstly, a visible or UV laser 190 produces visible or UV laser pulses 192 which are directed by visible or UV laser optics 194 to first remove surface layer 212 within street 218 and then through cut the wafer 210 following removal or deterioration of DAF 214 on tape 216 by IR laser pulses 198. Secondly, an IR laser 196 produces IR laser pulses 198 which are directed by IR laser optics 200 to perform backside removal or deterioration of DAF 214. The visible or UV laser 194 can be a Coherent Avia operating at 355 nm and the IR laser 196 can be a Coherent Diamond K-series CO2 laser operating at 9.6 microns. Visible and UV laser optics 194 are the same as the visible and UV laser optics 154, 174 and IR laser optics 200 are the same as IR optics 164.

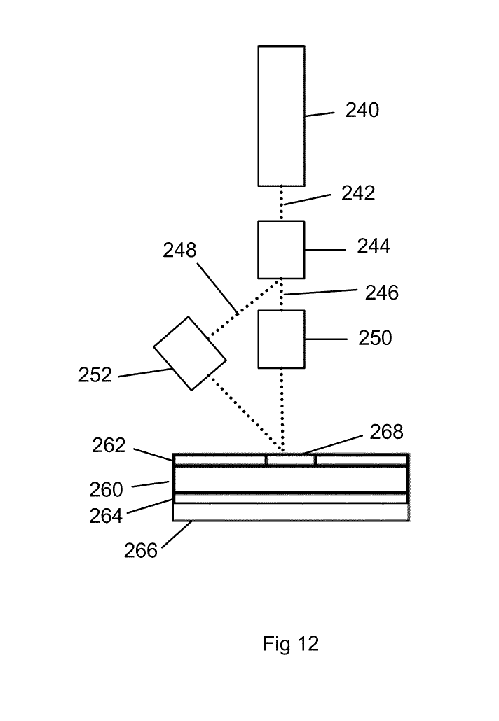

FIG. 12 shows the laser processing system adapted by using a single laser. The laser processing system is adapted by using single laser 240 which produces laser pulses 242 which can switch or be switched between IR pulses 248 and visible or UV pulses 246 by the optical switch 244. The system is further adapted by adding IR laser optics 252 and visible and UV laser optics 250 direct the visible or UV laser pulses 246 to first remove the surface layer 262 from within the street region 268 to expose the surface of the wafer 260, then to use IR laser optics 252 to direct the IR laser pulses 248 to perform backside removal or deterioration of the DAF 264 on tape 266 through the wafer 260, followed by using the visible or UV laser optics 250 to direct visible or UV laser pulses 246 to through cut the wafer.

In an embodiment of this invention the laser 240 is a member of the solid state laser family which includes both conventional solid-state diode pumped such as those employing Nd:VO4 crystals, fiber lasers which employ Nd-doped glass fibers and various combinations of conventional and fiber solid state lasers arranged as light pumps, resonators and amplifiers. The laser 240 could possibly include harmonic generating crystals such as monopotassium phosphate (KDP), lithium triborate (LBO) or B-barium borate (BBO) which convert IR radiation in the 1064 nm wavelength range to shorter wavelengths such as 532 nm (visible) or 355 nm (UV). This harmonic generating capability may be internal to the laser 240 or external as part of the optical switch 244 and arranged to permit the system to emit either IR pulses 248 or visible or UV pulses 246. The laser 240 or optical switch 244 may also include an optical parametric oscillator (OPO) which converts 1064 nm IR wavelengths to wavelengths longer than 1300 microns to improve transmission of laser radiation through the wafer 260. These pulses 246, 248 are directed to the street 268, wafer 260 or DAF 264 by the IR laser optics 252 or visible or UV optics 250 respectively. The IR optics 246 and visible or UV optics 250 are constructed similarly to their counterparts in FIGS. 10 and 11. In this case the laser processing system (not shown) must switch the laser power between low power, or about 10 to 20 W of power while removing material from the streets and through cutting to higher power, or more than 200 W of power while removing or deteriorating DAF by controlling the laser 240, the optical switch 244, the IR laser optics 252 or the visible or UV optics 250.

Laser pulse parameters for removing a layer or layers of material 182 to expose the wafer surface 180 include a wavelength between about 255 nm and 532 nm, a pulse width between 10 ps and 100 ns, pulse energy of between about 0.1 μJ and 1.0 mJ per pulse, pulse repetition rate of greater than 100 kHz and pulse shapes which include Gaussian, top hat (circular) or top hat (square). Laser parameters for backside removal of DAF 214 include a wavelength between about 1.064 microns and 10.6 microns, either pulsed or shuttered continuous wave (CW) operation, either pulse energy of greater than 10 μJ for pulsed operation or laser power of greater than 200 W in the case of CW operation, and pulse shapes which include Gaussian, top hat (circular) or top hat (square). Laser parameters for through cutting the wafer 180 include a wavelength between about 255 nm and 532 nm, a pulse width between 10 ps and 500 ns, pulse energy of between about 0.1 μJ and 10.0 μJ per pulse, pulse repetition rate of greater than 100 kHz and pulse shapes which include Gaussian, top hat (circular) or top hat (square).

Singulation of electronic devices from a wafer in this manner is efficient since the wafer does not have to be moved or re-aligned during the process as is required by other approaches to solving the problems associated with singulation of wafers on DAF. Embodiments of this invention also provide a substantially debris-free and undamaged wafer following singulation due to the limited amount of debris and thermal damage caused by removal of the DAF by infrared (IR) laser. In addition the DAF which remains attached to the electronic device by design is substantially debris-free and is trimmed accurately to the device. Advantages of using three lasers to process wafers in this fashion include greater throughput although at a greater system cost. Using two lasers can increase throughput to a lesser extent than using three lasers but at a lower incremental system cost. The solution using one laser may have the lowest system cost but correspondingly lower system throughput.

It will be apparent to those of ordinary skill in the art that many changes may be made to the details of the above-described embodiments of this invention without departing from the underlying principles thereof. The scope of the present invention should, therefore, be determined only by the following claims.

We claim:

1. An improved method for singulation of substrates mounted on die attach film with a laser processing system, said substrate having a surface opposite said die attach film having predefined streets and a layer of material on said surface, comprising:
providing said laser processing system with a first laser having first laser parameters;
providing said laser processing system with a second laser having second laser parameters;
providing said laser processing system with a third laser having third laser parameters;
determining a maximum surface texture of said substrate that permits backside removal of die attach film with said second laser having said second laser parameters;
determining said first laser parameters that permit said first laser to remove portions of said layer of material from said substrate in a desired region so that substantially all of said layer of material is removed from the desired region and the surface texture of the resulting surface within the desired region is less than said determined maximum surface texture;
directing said first laser to remove said layer of material from said substrate within a desired area substantially within said streets using said first laser parameters;
directing said second laser to perform backside removal of portions of said die attach film using said second laser parameters in regions aligned with said streets; and,
directing said third laser to perform through cuts in said substrate with said third laser within said streets thereby singulating said substrate.

2. The method of claim 1 wherein said first laser parameters include a wavelength between about 255 nm and about 532 nm, a pulse width of less than about 1000 ps, and pulse energy of greater than about 0.1 μJ.

3. The method of claim 1 wherein said second laser parameters include a wavelength of greater than about 1000 nm, a pulse width of greater than about 100 ns, and pulse energy of greater than about 10 μJ.

4. The method of claim 1 wherein said third laser parameters include a wavelength between about 255 nm and about 532 nm, a pulse width of less than about 500 ns, and pulse energy of greater than about 0.1 μJ.

5. The method of claim 1 wherein said first and third lasers are the solid state lasers and said second laser is a gas laser.

6. The method of claim 1 wherein said first, second and third lasers are solid state lasers.

7. The method of claim 1 wherein said first and third lasers are the same laser.

8. The method of claim 1 wherein said first, second and third lasers are the same laser.

9. An improved system for singulation of substrates mounted on die attach tape with a laser processing system, said substrate having a surface opposite said die attach film having predefined streets and a layer of material on said surface, comprising:
a first laser operative to remove portions of a first layer of material from said substrate in the region of said layer of material from said substrate in a desired region so that substantially all of said layer of material is removed from the desired region and the surface texture of the resulting surface within the desired region is less than a predetermined maximum surface texture;
a second laser operative to perform backside removal of portions of said die attach film using said second laser parameters in regions aligned with said streets; and,
a third laser operative to perform through cuts in said substrate with said third laser within said streets thereby singulating said substrate.

10. The method of claim 7 wherein said first laser parameters include a wavelength between about 255 nm and about 532 nm, a pulse width of less than about 1000 ps, and pulse energy of greater than about 0.1 μJ.

11. The method of claim 7 wherein said second laser parameters include a wavelength of greater than about 1000 nm, a pulse width of greater than about 100 ns, and pulse energy of greater than about 10 μJ.

12. The method of claim 7 wherein said third laser parameters include a wavelength between about 255 nm and about 532 nm, a pulse width of less than about 500 ns, and pulse energy of greater than about 0.1 μJ.

13. The method of claim 7 wherein said first and third lasers are the solid state lasers and said second laser is a gas laser.

14. The method of claim 7 wherein said first, second and third lasers are solid state lasers

15. The method of claim 7 wherein said first and third lasers are the same laser.

16. The method of claim 7 wherein said first, second and third lasers are the same laser.

17. An improved method for singulation of substrates mounted on die attach film with a laser processing system, said substrate having a surface opposite said die attach film having predefined streets and a layer of material on said surface, comprising:
providing said laser processing system with a first laser having first laser parameters;
providing said laser processing system with a second laser having second laser parameters;
providing said laser processing system with a third laser having third laser parameters;
determining a maximum surface texture of said substrate that permits backside deterioration of die attach film with said second laser having said second laser parameters;
determining said first laser parameters that permit said first laser to remove portions of said layer of material from said substrate in a desired region so that substantially all of said layer of material is removed from the desired region and the surface texture of the resulting surface within the desired region is less than said determined maximum surface texture;
directing said first laser to remove said layer of material from said substrate within a desired area substantially within said streets using said first laser parameters;
directing said second laser to perform backside deterioration of portions of said die attach film using said second laser parameters in regions aligned with said streets; and,
directing said third laser to perform through cuts in said substrate with said third laser within said streets thereby singulating said substrate.

18. The method of claim 17 wherein said first laser parameters include a wavelength between about 255 nm and about 532 nm, a pulse width of less than about 1000 ps, and pulse energy of greater than about 0.1 μJ.

19. The method of claim 17 wherein said second laser parameters include a wavelength of greater than about 1000 nm, a pulse width of greater than about 100 ns, and pulse energy of greater than about 10 μJ.

20. The method of claim 17 wherein said third laser parameters include a wavelength between about 255 nm and about 532 nm, a pulse width of less than about 500 ps, and pulse energy of greater than about 0.1 μJ.

21. The method of claim 17 wherein said first and lasers are the solid state lasers and said second laser is a gas laser.

22. The method of claim 17 wherein said first, second and third lasers are solid state lasers.

23. The method of claim 17 wherein said first and third lasers are the same laser.

24. The method of claim 17 wherein said first, second and third lasers are the same laser.
